(19) United States
(12) Patent Application Publication
(10) Pub. No.: US 2025/0011925 A1
(43) Pub. Date: Jan. 9, 2025

(54) SUBSTRATE PROCESSING APPARATUS, PROCESSING VESSEL, AND METHOD OF MANUFACTURING SEMICONDUCTOR DEVICE

(71) Applicant: Kokusai Electric Corporation, Tokyo (JP)

(72) Inventors: Motomu DEGAI, Toyama-shi (JP); Yukinori Aburatani, Toyama-shi (JP)

(73) Assignee: Kokusai Electric Corporation, Tokyo (JP)

(21) Appl. No.: 18/891,772

(22) Filed: Sep. 20, 2024

Related U.S. Application Data
(63) Continuation of application No. PCT/JP2022/014647, filed on Mar. 25, 2022.

(51) Int. Cl. C23C 16/44; C23C 16/458

(52) U.S. Cl. CPC C23C 16/4404; C23C 16/4583

(57) ABSTRACT

A substrate processing apparatus includes: a processing vessel provided with a processing space in which a substrate is processed; and a constituent member disposed in the processing space, in which a wall surface facing the processing space provided in the processing vessel and a surface of the constituent member facing the processing space are each covered with a fluorine-containing substance, and the fluorine-containing substance is selected according to a processing temperature of the substrate.

### CROSS-REFERENCE TO RELATED APPLICATION

This application is a Bypass Continuation Application of PCT International Application No. PCT/JP2022/014647, filed on Mar. 25, 2022, the entire contents of which are incorporated herein by reference.

### TECHNICAL FIELD

The present disclosure relates to a substrate processing apparatus, a processing vessel, and a method of manufacturing a semiconductor device.

### BACKGROUND

In some cases, as a step in a process of manufacturing a semiconductor device, the processing of forming a film on a substrate is performed. In such a film forming process, the substrate may be subjected to a preprocessing including an etching process. However, a constituent member of the gas used for the etching process remains in the processing chamber containing the substrate, and the remaining constituent member (may also be referred to as residue) adheres to the constituent member disposed in the processing vessel or the inner wall of the processing vessel, and may affect the quality of the substrate.

### SUMMARY

The present disclosure provides a technique enabling suppression of a residue of a gas used for substrate processing.

In one aspect of the present disclosure,
there is provided a technique that includes:
a processing vessel provided with a processing space in which a substrate is processed; and a constituent member disposed in the processing space, in which a wall surface facing the processing space in the processing vessel and a surface of the constituent member facing the processing space are each covered with a fluorine-containing substance, and the fluorine-containing substance is selected according to a processing temperature of the substrate.

### BRIEF DESCRIPTION OF DRAWINGS

FIG. 1 is a schematic configuration diagram of a substrate processing apparatus according one embodiment of the present disclosure, illustrating a processing furnace in a longitudinal cross section.

FIG. 2 is an enlarged longitudinal cross section of the processing furnace of the substrate processing apparatus according to one embodiment of the present disclosure.

FIG. 3 is a 3X-3X line cross section of the processing furnace illustrated in FIG. 2.

FIG. 4 is a side view illustrating a substrate support tool used in the substrate processing apparatus illustrated in FIG. 1.

FIG. 5 is a diagram illustrating a configuration of a control device of the substrate processing apparatus according to one embodiment of the present disclosure.

FIG. 6 is a diagram showing a flow of a substrate processing step according to one embodiment of the present disclosure.

FIG. 7A is a partial cross-sectional enlarged view of a surface of a wafer on which a base including a silicon oxide film and a base including a silicon nitride film are exposed on the surface.

FIG. 7B is a partially enlarged cross section of the surface of the wafer 200 after the surface of the base 200a is modified so as to be terminated with a hydrocarbon group by supplying a hydrocarbon group-containing gas.

FIG. 7C is a partially enlarged cross section of the surface of the wafer 200 after the first layer containing silicon and carbon is selectively formed on the surface of the base 200b by supplying a silicon-and halogen-containing gas.

FIG. 7D is a partially enlarged cross section of the surface of the wafer 200 after the first layer selectively formed on the surface of the base 200b is oxidized and modified to the second layer containing silicon, oxygen, and carbon by supplying an oxygen-and hydrogen-containing gas.

FIG. 7E is a partially enlarged cross section of the surface of the wafer 200 after a silicon oxycarbide film is selectively formed on the surface of the base 200b.

FIG. 7F is a partially enlarged cross section of the surface of the wafer 200 after a hydrocarbon group that terminates the surface of the base 200a is removed from the surface of the base 200a by post-processing the wafer 200 illustrated in FIG. 7E.

FIG. 8 is a schematic configuration diagram of a processing furnace according another embodiment of the present disclosure, illustrating the processing furnace in a longitudinal cross section.

### DETAILED DESCRIPTION

### First Embodiment of the Present Disclosure

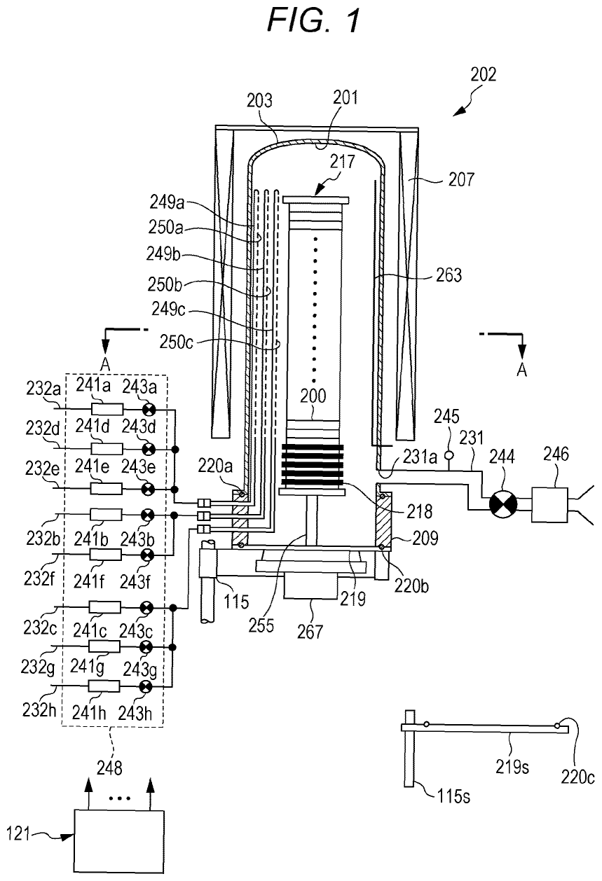

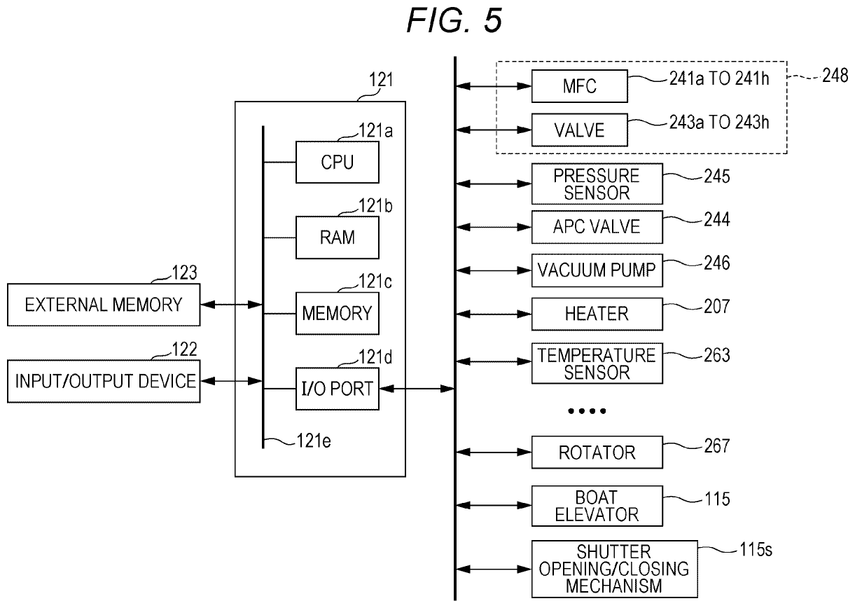

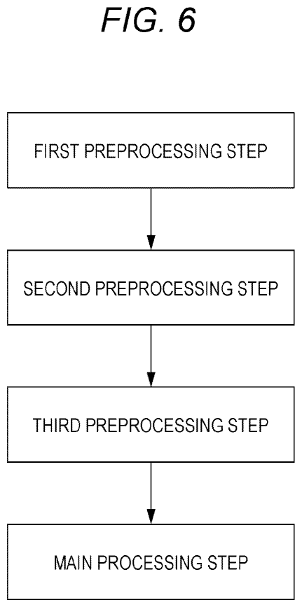

The first embodiment of the present disclosure will be described hereinafter mainly with reference to FIGS. 1 to 7. Note that the drawings used in the following description are all schematic and thus, for example, the dimensional relationship between each constituent element and the ratio between each constituent element illustrated in the drawings do not necessarily coincide with realities. Dimensional relationships between elements, ratios between elements and the like do not necessarily coincide between a plurality of drawings, too.

First, a substrate processing apparatus 100 according to the first embodiment of the present disclosure will be described.

### (1) Configuration of Substrate Processing Apparatus

As illustrated in FIG. 1, the substrate processing apparatus 100 according to the first embodiment includes a processing furnace 202.

The processing furnace 202 includes a heater 207 serving as a heating mechanism. The heater 207 has, for example, a cylindrical shape and is supported by a holding plate to be vertically installed. The heater 207 further serves as an activation mechanism that thermally activates gas.

Inside the heater 207, a reaction tube 203 is disposed concentrically with the heater 207. The reaction tube 203 is formed in a cylindrical shape (for example, a cylindrical shape) in which an upper end is closed and a lower end is open. The reaction tube 203 is formed of a heat-resistant material, such as quartz (SiO₂) or silicon carbide (SiC). The reaction tube 203 is vertically installed similarly to the heater 207.

A manifold 209 is disposed below the reaction tube 203 concentrically with the reaction tube 203. The manifold 209 is formed in a tubular shape (for example, a cylindrical shape) in which an upper end and a lower end are open. The manifold 209 is formed of, for example, a metal material such as stainless steel (SUS). The upper end of the manifold 209 engages with the lower end of the reaction tube 203 so as to support the reaction tube 203.

An O-ring 220a as a seal member is provided between the manifold 209 and the reaction tube 203.

In the present embodiment, the processing vessel 210 (in other words, reaction vessel) is configured mainly of the reaction tube 203 and the manifold 209. A processing chamber 201 is formed in a cylinder hollow portion of the processing vessel 210. The processing chamber 201 is capable of housing wafers 200 each serving as a substrate. The wafer 200 is processed in the processing chamber 201.

In the processing chamber 201, a nozzle 249a as a first supplier, a nozzle 249b as a second supplier, and a nozzle 249c as a third supplier are disposed so as to pass through a side wall of the manifold 209. The nozzle 249a, the nozzle 249b, and the nozzle 249c are also referred to as a first nozzle, a second nozzle, and a third nozzle, respectively. The nozzles 249a, 249b, and 249c are different nozzles. Each of the nozzles 249a and 249c is provided adjacent to the nozzle 249b. The nozzles 249a, 249b, and 249c are each formed of a heat-resistant material, such as quartz or SiC. A gas supply pipe 232a is connected to the nozzle 249a, a gas supply pipe 232b is connected to the nozzle 249b, and a gas supply pipe 232c is connected to the nozzle 249c.

The gas supply pipes 232a to 232c are provided with mass flow controllers (MFCs) 241a to 241c as flow rate controllers (flow rate controllers), and valves 243a to 243c as opening/closing valves, respectively, in this order from an upstream side of a gas flow. Gas supply pipes 232d and 232e are connected to the gas supply pipe 232a on a downstream side of the valve 243a. Gas supply pipes 232f, 232g, and 232h are respectively connected to the gas supply pipes 232b and 232c on a downstream side of the valves 243b and 243c. The gas supply pipes 232d to 232h are provided with MFCs 241d to 241h and valves 243d to 243h, respectively, in this order from the upstream side of the gas flow. The gas supply pipes 232a to 232h are each formed of, for example, a metal material such as SUS.

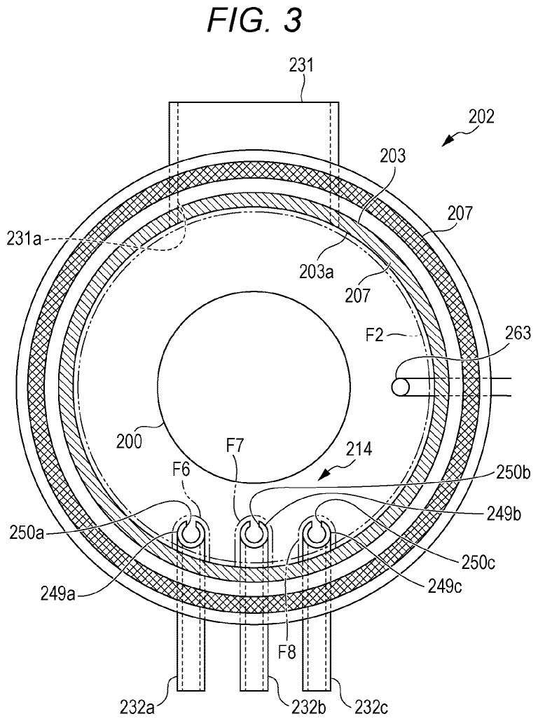

As illustrated in FIG. 3, the annular space in plan view between the inner wall of the reaction tube 203 and a wafer 200 is provided with the nozzles 249a, 249b and 249c each extending upward in the direction of an array of wafers 200 from the lower portion of the inner wall of the reaction tube 203.

In a plan view, the nozzle 249b is disposed so as to be opposed to an exhaust port 231a to be described later across the center of the wafer 200 loaded into the processing chamber 201. The nozzles 249a and 249c are disposed so as to sandwich the nozzle 249b from both sides along the inner wall of the reaction tube 203.

A gas supply hole 250a that supplies gas is provided on a lateral surface of the nozzle 249a. The gas supply hole 250a is opened so as to be opposed to (face) the exhaust port 231a in a plan view, and can supply a gas toward the wafer 200. A plurality of the gas supply holes 250a are formed from the lower portion to the upper portion of the reaction tube 203.

A gas supply hole 250b that supplies gas is disposed on a side surface of the nozzle 249b. The gas supply hole 250b is opened so as to be opposed to (face) the exhaust port 231a in a plan view, and can supply a gas toward the wafer 200. A plurality of the gas supply holes 250b are formed from the lower portion to the upper portion of the reaction tube 203.

A gas supply hole 250c that supplies gas is provided on a lateral surface of the nozzle 249c. The gas supply hole 250c is opened so as to be opposed to (face) the exhaust port 231a in a plan view, and can supply a gas toward the wafer 200. A plurality of the gas supply holes 250c are formed from the lower portion to the upper portion of the reaction tube 203.

A modifying gas is supplied from the gas supply pipe 232a into the processing chamber 201 via the MFC 241a, the valve 243a, and the nozzle 249a.

A source (source gas) is supplied from the gas supply pipe 232b into the processing chamber 201 via the MFC 241b, the valve 243b, and the nozzle 249b.

An oxidizing agent as a first reactant gas (oxidizing gas) is supplied from the gas supply pipe 232c into the processing chamber 201 via the MFC 241c, the valve 243c, and the nozzle 249c.

From the gas supply pipe 232d, a catalyst (catalyst gas) as the second reactant gas is supplied to the processing chamber 201 via the MFC 241d, the valve 243d, the gas supply pipe 232a, and the nozzle 249a.

An inert gas is supplied from the gas supply pipes 232e to 232g into the processing chamber 201 via the MFCs 241e to 241g, the valves 243e to 243g, the gas supply pipes 232a to 232c, and the nozzles 249a to 249c, respectively. The inert gas acts as a purge gas, a carrier gas, a diluent gas and the like.

An etching gas is supplied from the gas supply pipe 232h to the processing chamber 201 via the MFC 241h, the valve 243h, the gas supply pipe 232c, and the nozzle 249c.

A modifying gas supply system is configured mainly with the gas supply pipe 232a, the MFC 241a, and the valve 243a. A source gas supply system is configured mainly with the gas supply pipe 232b, the MFC 241b, and the valve 243b. An oxidizing gas supply system is configured mainly with the gas supply pipe 232c, the MFC 241c, and the valve 243c. A catalyst gas supply system is configured mainly with the gas supply pipe 232d, the MFC 241d, and the valve 243d. An inert gas supply system is configured mainly with the gas supply pipes 232e to 232g, the MFCs 241e to 241g, and the valves 243e to 243g. An etching gas supply system is configured mainly with the gas supply pipe 232h, the MFC 241h, and the valve 243h.

Any one or all of the various supply systems described above may be formed as an integrated supply system 248 in which the valves 243a to 243h, the MFCs 241a to 241h and the like are integrated. The integrated supply system 248 is connected to each of the gas supply pipes 232a to 232h, and is configured such that a supplying operation of various gases into the gas supply pipes 232a to 232h, that is, an opening/closing operation of the valves 243a to 243h, a flow rate regulating operation by the MFCs 241a to 241h and the like are controlled by a controller 121 to be described later.

The exhaust port 231a from which an atmosphere inside the processing chamber 201 is exhausted is formed in a lower portion of a side wall of the reaction tube 203. As illustrated in FIG. 3, the exhaust port 231a is provided at a position facing the nozzles 249a, 249b and 249c with the wafer 200 interposed therebetween in plan view. Specifically, the exhaust port 231a is provided at a position facing the gas supply holes 250a, 250b, and 250c. An exhaust pipe 231 is connected to the exhaust port 231a. A vacuum pump 246 serving as a vacuum exhaust is connected to the exhaust pipe 231 via a pressure sensor 245 serving as a pressure detector that detects the pressure inside the processing chamber 201 and an auto pressure controller (APC) valve 244 serving as a pressure regulator. The APC valve 244 is configured to be able to perform vacuum exhaust and vacuum exhaust suspension inside the processing chamber 201 by being opened and closed while the vacuum pump 246 is activated. Furthermore, the APC valve 244 can adjust a pressure inside the processing chamber 201 by adjusting a degree of valve opening on the basis of pressure information detected by the pressure sensor 245 while the vacuum pump 246 is activated.

In the present embodiment, an exhaust system is configured mainly by the exhaust pipe 231, the APC valve 244, and the pressure sensor 245.

A seal cap 219 as a furnace opening lid capable of hermetically closing the lower end opening of the manifold 209 is provided below the manifold 209. The seal cap 219 is formed in a disk shape. The seal cap 219 is formed of, for example, a metal material such as SUS. An O-ring 220b as a seal member that abuts the lower end of the manifold 209 is provided on an upper surface of the seal cap 219. A rotator 267 that rotates a boat 217 to be described later is disposed below the seal cap 219. A rotating shaft 255 of the rotator 267 penetrates the seal cap 219 and is connected to the boat 217. The rotator 267 is configured to rotate the boat 217, thereby rotating the wafer 200. A boat elevator 115 as an elevator disposed outside the reaction tube 203 is configured to vertically raise and lower the seal cap 219. The boat elevator 115 serves as a conveyor that raises/lowers the seal cap 219 to convey (load/unload) wafers 200 into/from the processing chamber 201.

Below the manifold 209, a shutter 219s as a furnace opening lid capable of hermetically closing the lower end opening of the manifold 209 in a state in which the seal cap 219 is lowered and the boat 217 is unloaded from the inside of the processing chamber 201 is provided. The shutter 219s is formed in a disk shape. The shutter 219s is formed of, for example, a metal material such as SUS. An O-ring 220c as a seal member that abuts the lower end of the manifold 209 is provided on an upper surface of the shutter 219s. An opening/closing operation (a lifting operation, a turning operation, and the like) of the shutter 219s is controlled by a shutter opening/closing mechanism 115s.

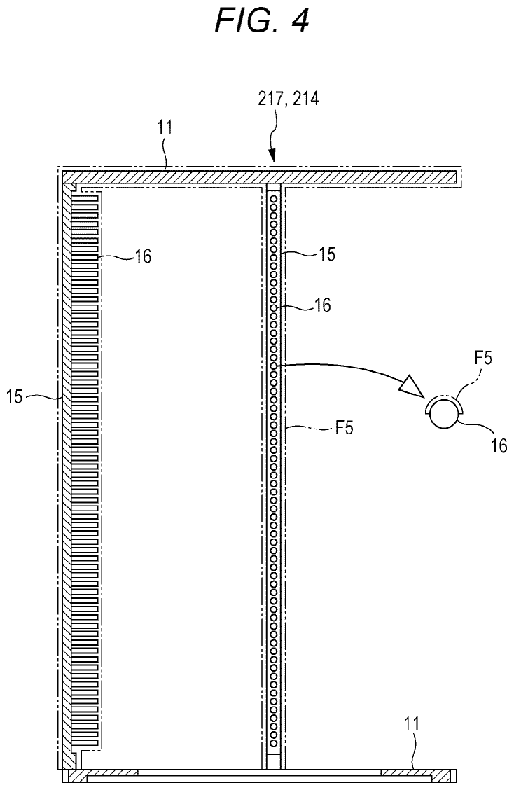

The boat 217 as a substrate support tool is configured to support a plurality of, for example, 25 to 200 wafers 200 horizontally, in multiple stages so as to be aligned vertically with the centers aligned with one another, that is, to arrange at intervals. The boat 217 is made of, for example, a heat-resistant material such as quartz or SiC. The boat 217 may also be formed of a metal material such as SUS. Heat insulating plates 218 each formed of, for example, a heat-resistant material such as quartz or SiC are supported in multiple stages in a lower portion of the boat 217. Specifically, as illustrated in FIG. 4, the boat 217 includes a bottom plate 12 and a top plate 11 as two parallel plates, and a plurality of supporting rods 15, for example, three supporting rods provided substantially vertically between the bottom plate 12 and the top plate 11. The supporting rod 15 has, for example, a columnar shape. The three supporting rods 15 are arrayed in a substantially semicircular shape and fixed to the bottom plate 12. The top plate 11 is fixed to the upper ends of the three supporting rods 15. As illustrated in FIG. 4, in each supporting rod 15, supporting pins 16 as a plurality of support portions that can arrange the plurality of wafers 200 at predetermined intervals in the vertical direction and support (in other words, place) the plurality of wafers 200 in a substantially horizontal posture are provided in multiple stages. The supporting pin 16 is made of, for example, a heat-resistant material such as quartz or SiC. The supporting pin 16 may also be made of, similarly to the supporting rod 15, stainless steel. Each supporting pin 16 has a columnar shape as an example, and protrudes toward the inside of the boat 217. That is, the supporting pin 16 protrudes toward the center of the boat 217 (the center of the wafer 200). In this case, one supporting pin 16 is provided in each of the supporting rods 15. That is, three supporting pins 16 protrude from each stage. The protruding three supporting pins 16 supports the outer periphery of the wafer 200, whereby the wafer 200 is supported.

A temperature sensor 263 as a temperature detector is disposed in the reaction tube 203. By regulating a degree of energization to the heater 207 on the basis of temperature information detected by the temperature sensor 263, a desired temperature distribution can be achieved in the processing chamber 201. The temperature sensor 263 is disposed along the inner wall of the reaction tube 203.

As illustrated in FIG. 5, a controller 121 as a control section, is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 formed as, for example, a touch panel and the like is connected to the controller 121.

The memory 121c includes, for example, a flash memory or a hard disk drive (HDD). A control program for controlling an operation of the substrate processing apparatus, a process recipe in which procedures, conditions and the like of substrate processing to be described later are described and the like are readably stored in the memory 121c. The process recipe is combined so as to function as a program that causes the controller 121 to perform each procedure in the substrate processing, described later, to obtain a predetermined result. Hereinafter, the process recipe, the control program, and the like are also collectively and simply referred to as a program. The process recipe is simply referred to as a recipe. In a case where the term “program” is used in the present specification, this may include the recipe alone, the control program alone, or both of them. Furthermore, the RAM 121b is configured as a memory area (in other words, work area) in which programs, data, and the like read by the CPU 121a are temporarily held.

The I/O port 121d is connected to the MFCs 241a, 241b, 241c, 241d, 241e, 241f, 241g and 241h, the valves 243a, 243b, 243c, 243d, 243e, 241f, 241g and 241h, the pressure sensor 245, the APC valve 244, the vacuum pump 246, the temperature sensor 263, the heater 207, the rotator 267, the boat elevator 115, the shutter opening/closing mechanism 115s, and the like described above.

The CPU 121a reads the control program from the memory 121c and executes the control program, and additionally reads the recipe from the memory 121c in response to an operation command input from the input/output device 122. The CPU 121a is configured to control, in accordance with a content of the read recipe, a flow rate regulating operation of various substances (various gases) by the MFCs 241a, 241b, 241c, 241d, 241e, 241f, 241g and 241h, an opening/closing operation of the valves 243a, 243b, 243c, 243d, 243e, 243f, 243g and 243h, a pressure regulating operation by the APC valve 244 based on an opening/closing operation of the APC valve 244 and the pressure sensor 245, start and stop of the vacuum pump 246, a temperature regulating operation of the heater 207 based on the temperature sensor 263, rotation and rotating speed regulating operation rotation of the boat 217 by the rotator 267, an elevating operation of the boat 217 by the boat elevator 115, an opening/closing operation of the shutter 219s by the shutter opening/closing mechanism 115s and the like.

The controller 121 can be achieved due to installation of the above-described program stored in the external memory 123 into the computer. Examples of the external memory 123 include a magnetic disk such as a HDD, an optical disc such as a CD, a magneto-optical disc such as an MO, and a semiconductor memory such as a USB memory. The memory 121c and the external memory 123 are formed as computer-readable recording media. Hereinafter, the memories are also collectively and simply referred to as a recording medium. In a case where the term “recording medium” is used in the present specification, this may include the memory 121c alone, the external memory 123 alone, or both of them. Note that, the program may be provided to the computer not by using the external memory 123 but by using a communication means such as the Internet or a dedicated line.

### (Fluorine-Containing Coating Substance)

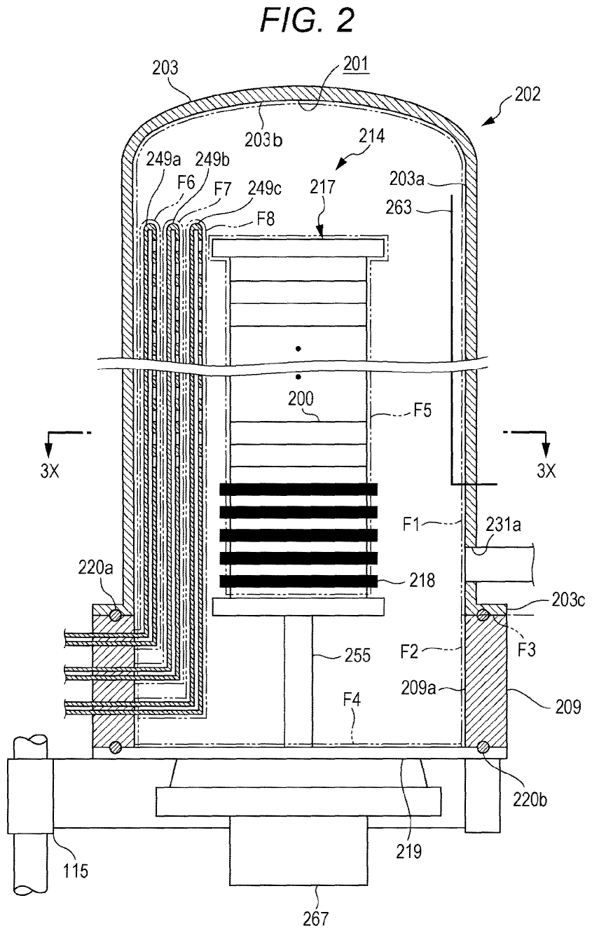

As illustrated in FIG. 2, in the substrate processing apparatus 100 according to the present embodiment, a wall surface facing the processing space 212 in the processing vessel 210 and a surface of the constituent member 214 facing the processing space 212 are each covered with a fluorine-containing substance. Note that the constituent member 214 in the present embodiment includes the boat 217, the nozzle 249a, the nozzle 249b, and the nozzle 249c, but the present disclosure is not limited thereto, and for example, the reaction tube 203 and the manifold 209 can also be included in the constituent member 214. Furthermore, although not covered with the fluorine-containing substance in FIG. 2, the rotating shaft 255 and the shutter 219s (in particular, the wall surface side facing the processing space 212) (as a part of the boat 217) are also preferably configured to be covered with the fluorine-containing substance as the constituent member 214.

In the present embodiment, a processing vessel 210 is formed by the reaction tube 203 and the manifold 209. That is, the processing space 212 of the processing vessel 210 is configured by the internal space of the reaction tube 203 (processing chamber 201) and the internal space of the manifold 209.

As shown in FIG. 2, the inner wall surface of the reaction tube 203 constituting the processing vessel 210 is covered with a fluorine-containing substance. As an example, in the present embodiment, the entire inner peripheral surface 203a and the entire ceiling surface 203b of the reaction tube 203 are covered with the fluorine-containing substance F1. Specifically, the entire inner peripheral surface 203a and the entire ceiling surface 203b of the reaction tube 203 are covered with a fluorine-based resin which is the fluorine-containing substance F1. In FIGS. 2 and 3, a region of the reaction tube 203 covered with the fluorine-containing substance F1 is indicated by a two-dot chain line.

An inner wall surface of the manifold 209 constituting the processing vessel 210 is covered with a fluorine-containing substance. As an example, in the present embodiment, the entire inner peripheral surface 209a of the manifold 209 is covered with the fluorine-containing substance F2. Specifically, the entire inner peripheral surface 209a of the manifold 209 is covered with a fluorine-based resin which is a fluorine-containing substance F2. In FIG. 2, a region of the manifold 209 covered with the fluorine-containing substance F2 is indicated by a two-dot chain line.

A flange 203c projecting outward is provided at a lower end portion of the reaction tube 203. The flange 203c is supported by the upper end portion of the manifold 209. The O-ring 220a is provided between the flange 203c of the reaction tube 203 and the upper end of the manifold 209. A surface (lower surface in the drawing) of the flange 203c is covered with the fluorine-containing substance F3. Specifically, the surface of the flange 203c is covered with a fluorine-based resin which is a fluorine-containing substance F3. In FIG. 2, a region of the flange 203c covered with the fluorine-containing substance F3 is indicated by a two-dot chain line.

A surface (upper surface) of the seal cap 219 is covered with a fluorine-containing substance. As an example, in the present embodiment, the entire surface of the seal cap 219 is covered with the fluorine-containing substance F4. Specifically, the entire surface of the seal cap 219 is covered with a fluorine-based resin which is fluorine-containing substance F4. In FIG. 2, a region of the seal cap 219 covered with the fluorine-containing substance F4 is indicated by a two-dot chain line.

The surface of the boat 217 is covered with a fluorine-containing substance. On the other hand, the boat 217 may be configured such that a portion facing the processing space 212 is covered with the fluorine-containing substance, and a portion not facing the processing space 212 is not covered with the fluorine-containing substance. As an example, the entire supporting rod 15, the entire bottom plate 12, and the entire top plate 11 of the boat 217 are covered with the fluorine-containing substance F5. On the other hand, as shown in FIG. 4, the lower end portion (bottom plate 12) of the boat 217 may be configured not to be covered with the fluorine-containing substance under the condition that the lower end portion does not face the processing space 212, but of course, it is preferable to cover the lower end portion with the fluorine-containing substance F5. In addition, since a portion of the surface of the supporting pin 16 that is in contact with the wafer 200 does not face the processing space 212 due to the wafer 200, it may be configured not to be covered with the fluorine-containing substance. The fluorine-containing substance covering the surface of the supporting pin 16 preferably has the largest friction coefficient among the fluorine-containing substances. In FIG. 4, a region of the boat 217 covered with the fluorine-containing substance F5 is indicated by a two-dot chain line.

In addition, the boat 217 may be made of a material having high thermal conductivity, for example, metal. However, when metal is exposed to the processing space 212, metal contamination occurs, and thus a portion facing the processing space 212 is covered with at least the fluorine-containing substance F5.

Surfaces of the nozzle 249a, the nozzle 249b, and the nozzle 249c are covered with a fluorine-containing substance. Specifically, the surface of the portion of the nozzle 249a facing the processing space 212, in other words, the portion of the nozzle 249a in the processing space 212 is covered with the fluorine-containing substance F6. That is, the surface of the nozzle 249a is covered with a fluorine-based resin which is the fluorine-containing substance F6. In FIGS. 2 and 3, a region of the nozzle 249a covered with the fluorine-containing substance F6 is indicated by a two-dot chain line. Similarly to the nozzle 249a, the surface of a portion of the nozzle 249b facing the processing space 212, in other words, a portion of the nozzle 249b in the processing space 212 is covered with the fluorine-containing substance F7. In FIGS. 2 and 3, a region of the nozzle 249b covered with the fluorine-containing substance F7 is indicated by a two-dot chain line. Similarly to the nozzle 249a, the surface of a portion of the nozzle 249c facing the processing space 212, in other words, a portion of the nozzle 249c facing the processing space 212 is covered with the fluorine-containing substance F8. In FIGS. 2 and 3, a region of the nozzle 249c covered with the fluorine-containing substance F8 is indicated by a two-dot chain line.

In the present embodiment, covering the wall surface of the processing vessel 210 and the surfaces of the boat 217, the nozzle 249a, the nozzle 249b, and the nozzle 249c with the above-described fluorine-containing substances F1, F2, F3, F4, F5, F6, F7, and F8 used in the substrate processing apparatus 100 may be hereinafter treated as being C-F terminated (terminated with a fluorine-containing substance). Since there is no chemically active site on the C-F-terminated surface, and the dispersion force is small due to the high electronegativity of F (fluorine), chemical adsorption and physical adsorption of molecules of any processing gas (etching gas, source gas, and the like) hardly occur. Therefore, it is extremely low that the processing gas reacts in a region other than the wafer 200 due to the fluorine-containing substance covering the wall surface and the like of the processing vessel 210. Furthermore, a reaction with the processing gas (chemical adsorption and physical adsorption of molecules) hardly occurs regardless of the film type and the process. However, for example, since the recommended use temperature of PTFE (polytetrafluoroethylene) as the fluorine-containing substance is 260° C. or lower, the temperature in the processing vessel 210 is preferably this recommended use temperature or lower.

The fluorine-containing substances F1, F2, F3, F4, F5, F6, F7, and F8 (hereinafter, it is abbreviated as a “fluorine-containing substance F”) used in the substrate processing apparatus 100 are selected according to, for example, the processing temperature of the wafer 200.

In the present embodiment, each portion is configured to be covered with a different fluorine-containing substance according to the position of the wall surface of the processing vessel 210, the surface of each of the boat 217, the nozzle 249a, the nozzle 249b, and the nozzle 249c, and the wafer 200 arranged in the processing space 212. Specifically, the fluorine-containing substance F1 covering the inner wall surface of the reaction tube 203 has a higher infrared transmittance than the fluorine-containing substances F5, F6, F7, and F8 covering the surfaces of the boat 217, the nozzle 249a, the nozzle 249b, and the nozzle 249c.

In addition, in the substrate processing apparatus 100 of the present embodiment, the processing temperature of the wafer 200 is set to be lower than the heat-resistant temperature of the fluorine-containing substance. Specifically, the highest processing temperature in the substrate processing step to be described later is set to be lower than the heat-resistant temperature of the fluorine-containing substance described above.

Next, a substrate processing step according to an embodiment of the present disclosure will be described.

### (2) Substrate Processing Step

One step of the manufacturing process of the semiconductor device will be described using the above-described substrate processing apparatus 100. In the following description, an operation of each unit included in the substrate processing apparatus 100 is controlled by the controller 121.

### (Wafer Charge and Boat Load)

When a plurality of wafers 200 is loaded on the boat 217 (wafer charge), the shutter opening/closing mechanism 115s moves the shutter 219s, and the lower end opening of the manifold 209 is opened. Thereafter, as illustrated in FIG. 1, the boat 217 that supports the plurality of wafers 200 is raised by the boat elevator 115 and is loaded into the processing chamber 201 (boat load). The lower end of the manifold 209 is sealed by the seal cap 219 via the O-ring 220b.

### (First Preprocessing Step)

Next, the natural oxide film of the wafer 200 is removed. An etching gas is used to remove the natural oxide film of the wafer 200. The valve 243h is opened to allow the etching gas to flow from the gas supply pipe 232b into the nozzle 249b, and the etching gas is supplied to the processing chamber 201 via the nozzle 249h. In the first preprocessing step, the processing chamber 201 is vacuum exhausted in advance, the processing chamber 201 is heated to a predetermined temperature (for example, 100° C.), and the etching gas is supplied to the processing chamber 201 in a state where the valve 243h is opened.

The valve 243h is opened and closed every certain time (opening and closing of the valve 243h are repeated every certain time), and the natural oxide film of the wafer 200 is etched with an etching gas. When the etching is completed, the valve 243h and the valve 243g are closed to vacuum the processing chamber 201, and then the valve 243g is opened to purge the processing chamber 201 with an inert gas.

As the etching gas, an F-containing gas such as a hydrogen fluoride (HF) gas, an ammonium trifluoride (NF₃) gas, or a chlorine trifluoride (ClF₃) gas may be used, or a Cl-containing gas such as a boron trichloride (BCl₃) gas may be used. This step (first preprocessing step) is not essential, and this step can be omitted as long as the influence of the natural oxide film can be ignored.

### (Second Preprocessing Step)

Next, a step of terminating a partial region by OH will be described. In the present embodiment, the etching gas is removed from the wafer 200. An oxygen (O)- and hydrogen (H)-containing gas is used as an oxidant (oxidizing gas) for removal of the etching gas. For example, water vapor (H₂O gas) is supplied from the above-described oxidizing gas supply system to the processing chamber 201 via a water vapor generator (not illustrated), and is exhausted from the exhaust pipe 231. Since water vapor (H₂O gas) comes into contact with halogen species and reacts with the halogen species to be discarded, the halogen species are removed. In the second preprocessing step, the processing chamber 201 is heated to a predetermined temperature (for example, 200° C.), and water vapor is supplied to the processing chamber 201. When the purging with water vapor is completed, the processing chamber 201 is evacuated, and then the valve 243f is opened to purge the processing chamber 201 with an inert gas. Note that this step (second preprocessing step) is not essential similarly to the first preprocessing step, but it is preferable to perform this step depending on the target process (for example, an oxide film and the like).

### (Third Preprocessing Step)

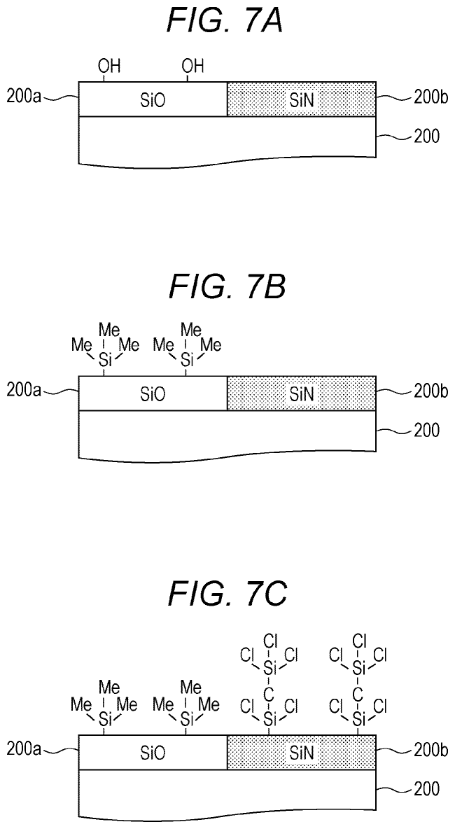

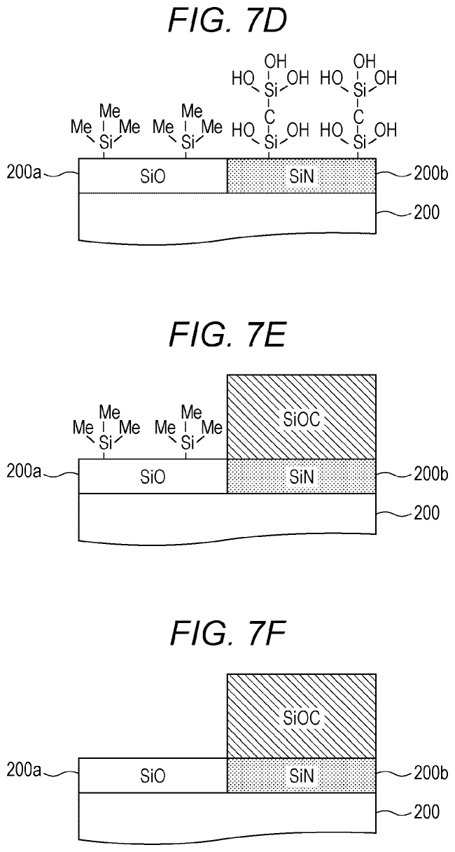

As illustrated in FIG. 7A, by the first preprocessing step and the second preprocessing step, a plurality of types of bases, here, as an example, the base 200a including an oxygen (O)-containing film, that is, a SiO film as an oxide film, and the base 200b including an O-free film, that is, a non-oxide film (for example, a SiN film as a nitride film) are exposed on the surface of the wafer 200. The base 200a has a surface terminated with a hydroxyl group (OH) (hereinafter referred to as OH termination) over the entire area (entire surface). The base 200b has a surface on which many regions are not OH-terminated, that is, a surface on which some regions are OH-terminated.

The vacuum pump 246 performs vacuum exhaust such that the inside of the processing chamber 201, that is, a space where the wafers 200 are present has a desired pressure (degree of vacuum). In this event, the pressure in the processing chamber 201 is measured by the pressure sensor 245, and the APC valve 244 is feedback-controlled based on information on the measured pressure. The heater 207 heats in such a manner that the wafer 200 in the processing chamber 201 reaches desired processing temperature. In this case, on the basis of the temperature information detected by the temperature sensor 263, the degree of energization to the heater 207 is feedback-controlled in such a manner that a desired temperature distribution is obtained in the processing chamber 201. The rotator 267 starts to rotate the wafer 200. The exhaust in the processing chamber 201, the heating and the rotation of the wafer 200 continue at least until the processing on the wafer 200 is finished.

Next, a hydrocarbon group-containing gas as a modifying gas is supplied to the wafer 200 in which the base 200a and the base 200b are exposed on the surface.

The valve 243a is opened, and the modifying gas flows into the gas supply pipe 232a. A flow rate of the modifying gas is regulated by the MFC 241a, and the source gas is supplied into the processing chamber 201 via the nozzle 249a and exhausted from the exhaust port 231a. In this case, the modifying gas is supplied to the wafer 200 (hydrocarbon group-containing gas supply). At that time, the valves 243e to 243g may be opened to supply the inert gas into the processing chamber 201 via the nozzles 249a to 249c, respectively.

By supplying the modifying gas to the wafer 200 under the processing conditions described later, it is possible to selectively (preferentially) modify the surface of the base 200a among the bases 200a and 200b. Specifically, it is possible to selectively (preferentially) adsorb Si contained in the modifying gas onto the surface of the base 200a by reacting the OH group terminating the surface of the base 200a with the modifying gas while suppressing adsorption of Si contained in the modifying gas onto the surface of the base 200b. As a result, the surface of the base 200a can be terminated with, for example, the methyl group (Me) contained in the modifying gas. Specifically, as shown in FIG. 7B, the surface of the base 200a can be terminated with a trimethylsilyl group (Si-Me₃) contained in the modifying gas. The methyl group (trimethylsilyl group) that terminates the surface of the base 200a prevents the adsorption of the source gas (Si and halogen-containing gas) to the surface of the base 200a in the selective growth described later, and acts as an adsorption inhibitor (inhibitor) that inhibits the progress of the film forming reaction on the surface of the base 200a.

After the surface of the base 200a is modified, the valve 243a is closed, and the supply of the modifying gas into the processing chamber 201 is stopped. Then, the inside of the processing chamber 201 is vacuum-exhausted to remove the gas and the like remaining in the processing chamber 201 from the inside of the processing chamber 201. At that time, the valves 243e to 243g are opened to supply the inert gas into the processing chamber 201 via the nozzles 249a to 249c. The inert gas supplied from the nozzles 249a to 249c acts as a purge gas. Accordingly, the inside of the processing chamber 201 is purged (purge).

As processing conditions in the modifying gas supply,
modifying gas supply flow rate: 1 to 3,000 sccm, preferably 1 to 500 sccm,
modifying gas supply time: 1 second to 120 minutes, preferably 30 seconds to 60 minutes,
inert gas supply flow rate (per gas supply pipe): 0 to 20,000 sccm,
processing temperature: room temperature (25° C.) to 500° C., preferably room temperature to 250° C., more preferably room temperature to 200° C., and processing pressure: 5 to 1,000 Pa
are exemplified.

As processing conditions in the purge,
inert gas supply flow rate (per gas supply pipe): 500 to 20,000 sccm
inert gas supply time: 10 to 30 seconds and,
processing pressure: 1 to 30 Pa
are exemplified.

Note that the expression of a numerical range such as “5 to 1000 Pa” in the present specification means that the lower limit and the upper limit are included in the range. Therefore, for example, “5 to 1,000 Pa” means “not less than 5 Pa and not more than 1,000 Pa”. The same applies to other numerical ranges.

As the hydrocarbon group-containing gas as the modifying gas, for example, a gas containing an alkyl group can be used. As the gas containing an alkyl group, for example, a gas containing an alkylsilyl group in which an alkyl group is coordinated to silicon (Si), that is, an alkylsilane-based gas can be used. The alkyl group is a generic term for the remaining atomic groups obtained by removing one hydrogen (H) atom from an alkane (chain saturated hydrocarbon represented by the general formula CₙH₂ₙ₊₂), and is a functional group represented by the general formula CₙH₂ₙ₊₁. Examples of the alkyl group include a methyl group, an ethyl group, a propyl group, and a butyl group. Since the alkyl group is bonded to Si which is the central atom of the alkylsilane molecule, the alkyl group in the alkylsilane can also be referred to as a ligand (ligand) or an alkyl ligand.

The hydrocarbon group-containing gas may further contain an amino group. As the hydrocarbon group-containing gas and the amino group-containing gas, for example, an alkylaminosilane-based gas can be used. The amino group is a functional group (a functional group in which one or both of H of an amino group represented by NH₂ are substituted with a hydrocarbon group containing one or more C atoms,) in which one or two hydrocarbon groups containing one or more carbon (C) atoms are coordinated to one nitrogen (N) atom. When two hydrocarbon groups constituting a part of the amino group are coordinated to one N, the two may be the same hydrocarbon group or different hydrocarbon groups. The hydrocarbon group may contain a single bond such as an alkyl group, or may contain an unsaturated bond such as a double bond or a triple bond.

As the hydrocarbon group-containing gas, in addition to a dimethylaminotrimethylsilane ((CH₃)₂NSi(CH₃)₃, abbreviation: DMATMS) gas, for example, an aminosilane-based gas represented by the following general formula [1] can be used.

SiAₓ[(NB₂)₍₄₋ₓ₎] [1]

In the formula [1], A represents an alkyl group such as a hydrogen atom, a methyl group, an ethyl group, a propyl group, or a butyl group, or an alkoxy group such as a methoxy group, an ethoxy group, a propoxy group, or a butoxy group. The alkyl group may be not only a linear alkyl group but also a branched alkyl group such as an isopropyl group, an isobutyl group, a secondary butyl group, or a tertiary butyl group. The alkoxy group may be not only a linear alkoxy group but also a branched alkoxy group such as an isopropoxy group or an isobutoxy group. B represents a hydrogen atom or an alkyl group such as a methyl group, an ethyl group, a propyl group, or a butyl group. The alkyl group may be not only a linear alkyl group but also a branched alkyl group such as an isopropyl group, an isobutyl group, a secondary butyl group, or a tertiary butyl group. A plurality of A may be the same or different, and two B may be the same or different. x is an integer of 1 to 3.

As the inert gas, a nitrogen (N₂) gas or a rare gas such as an argon (Ar) gas, a helium (He) gas, a neon (Ne) gas, or a xenon (Xe) gas can be used. One or more of these gases can be used as the inert gas. The same applies to each step described later.

### (Main Processing Step)

Thereafter, following Steps 1 and 2 are sequentially executed. In these steps, the output of the heater 207 is adjusted to maintain a state in which the temperature of the wafer 200 is equal to or lower than the temperature of the wafer 200 in the surface modification, preferably, a state in which the temperature is lower than the temperature of the wafer 200 in the surface modification.

### [Step 1]

In this step, Si and a halogen-containing gas as source gases and a catalyst are supplied to the wafer 200 in the processing chamber 201, that is, the wafer 200 after the surface of the base 200a is selectively terminated with a methyl group.

Specifically, the valves 243b and 243d are opened, and the source gas is allowed to flow into the gas supply pipe 232b and the catalyst is allowed to flow into the gas supply pipe 232d, respectively. The flow rate of the source gas and the flow rate of the catalyst are regulated by the MFCs 241b and 241d, respectively, and the source gas and the catalyst are supplied into the processing chamber 201 through the nozzles 249b and 249a, respectively, mixed in the processing chamber 201, and exhausted through the exhaust port 231a. At this time, the source gas and the catalyst are supplied to the wafers 200 (Si and halogen-containing gas+catalyst supply). At that time, the valves 243e to 243g may be opened to supply the inert gas into the processing chamber 201 via the nozzles 249a to 249c, respectively.

By supplying the source gas and the catalyst to the wafers 200 under the processing conditions described later, as illustrated in FIG. 7C, it is possible to selectively (preferentially) adsorb Si contained in the source gas to the surface of the base 200b while suppressing adsorption of Si contained in the source gas to the surface of the base 200a. As a result, a Si-containing layer containing C and Cl and having a thickness of, for example, less than one atomic layer (one molecular layer) to about several atomic layers (several molecular layers) is formed as the first layer on the surface of the base 200b. The first layer is a layer containing a Si-C bond. In the present specification, the Si-containing layer containing C and Cl is also simply referred to as a Si-containing layer containing C, or a SiC layer.

In this step, for example, by supplying the catalyst together with the source gas, the above-described reaction can be allowed to proceed under a non-plasma atmosphere or under a low temperature condition as described later. As described above, by forming the first layer under a non-plasma atmosphere or under a low temperature condition as described later, the methyl group terminating the surface of the base 200a can be maintained without being eliminated (desorbed) from the surface of the base 200a.

In this step, when the first layer is formed, Si contained in the source gas may be adsorbed to a part of the surface of the base 200a, but the adsorption amount thereof is smaller than the adsorption amount of Si to the surface of the base 200b. Such selective (preferential) adsorption becomes possible because the processing condition in this step is set to a condition under which the source gas does not undergo gas phase decomposition in the processing chamber 201. In addition, this is because the surface of the base 200a is terminated with methyl groups over the entire area, whereas many regions of the surface of the base 200b are not terminated with methyl groups. In this step, since the source gas is not vapor-phase decomposed in the processing chamber 201, Si contained in the source gas is not multiply deposited on the surfaces of the bases 200a and 200b, and Si contained in the source gas is selectively adsorbed to the surface of the base 200b.

After the first layer is selectively formed on the surface of the base 200b, the valves 243b and 243d are closed, and the supply of the source gas and the catalyst into the processing chamber 201 is stopped. Then, based on a processing procedure and processing conditions similar to those for the purge in the surface modification, for example, the gas remaining in the processing chamber 201 is eliminated from the processing chamber 201 (purge).

As processing conditions in this step,
source gas supply flow rate: 1 to 2,000 sccm,
catalyst supply flow rate: 1 to 2,000 sccm,
inert gas supply flow rate (per gas supply pipe): 0 to 20,000 sccm,
supply time of each gas: 1 to 60 seconds,
processing temperature: room temperature to 120° C., preferably room temperature to 90° C., and
processing pressure: 133 to 1,333 Pa
are exemplified.

As the source gas, Si and a halogen-containing gas are used. Halogen includes chlorine (Cl), fluorine (F), bromine (Br), iodine (I) and the like. The Si and halogen-containing gas preferably contains halogen in the form of a chemical bond between Si and halogen. The Si and halogen-containing gas may further contain C, and in that case, it is preferable to contain C in the form of a Si-C bond. As the Si- and halogen-containing gas, for example, a silane-based gas containing Si, Cl, and an alkylene group and having a Si-C bond, that is, an alkylene chlorosilane-based gas can be used. Examples of the alkylene group include a methylene group, an ethylene group, a propylene group, and a butylene group. The alkylene chlorosilane-based gas preferably contains Cl in the form of a Si-Cl bond and C in the form of a Si-C bond.

As the Si- and halogen-containing gas, for example, an alkylchlorosilane-based gas such as a bis(trichlorosilyl)methane ((SiCl₃)₂CH₂, abbreviated as BTCSM) gas or a 1,2-bis(trichlorosilyl)ethane ((SiCl₃)₂C₂H₄, abbreviated as BTCSE) gas; an alkylchlorosilane-based gas such as a 1,1,2,2-tetrachloro-1,2-dimethyldisilane ((CH₃)₂Si₂Cl₄, abbreviated as TCDMDS) gas or a 1,2-dichloro-1,1,2,2-tetramethyldisilane (CH₃)₄Si₂Cl₂, abbreviated as DCTMDS) gas; or a gas containing a cyclic structure composed of Si and C such as a 1,1,3,3-tetrachloro-1,3-disilacyclobutane (C₂H₄Cl₄Si₂, abbreviated as TCDSCB) gas and a halogen can be used. As the Si and halogen-containing gas, an inorganic chlorosilane-based gas such as tetrachlorosilane (SiCl₄, abbreviation: STC) gas, hexachlorodisilane (Si₂Cl₆, abbreviation: HCDS) gas, or octachlorotrisilane (Si₃Cl₈, abbreviation: OCTS) gas can also be used. Even when an inorganic chlorosilane-based gas is used, the same reaction as described above can be caused except that the first layer does not contain C.

As the catalyst, a cyclic amine gas such as a pyridine (C₅H₅N) gas, an aminopyridine (CH₆N₂) gas, a picoline (C₆H₇N) gas, a lutidine (C₇H₉N) gas, a piperazine (C₄H₁₀N₂) gas, or a piperidine (C₆H₁₁N) gas, or a chain amine gas such as a triethylamine ((C₂H₅)₃N, abbreviation: TEA) gas or a diethylamine ((C₂H₅)₂NH, abbreviation: DEA) gas can also be used. The same applies to Step 2 described later.

### [Step 2]

After the first layer is formed, an oxidizing gas and a catalyst are supplied to the wafers 200 in the processing chamber 201, that is, the first layer selectively formed on the surface of the base 200b.

Specifically, the valves 243c and 243d are opened to allow the oxidizing gas to flow into the gas supply pipe 232c and the catalyst to flow into the gas supply pipe 232d, respectively. The flow rate of the oxidizing gas and the flow rate of the catalyst are regulated by the MFCs 241c and 241d, respectively, and the source gas and the catalyst are supplied into the processing chamber 201 through the nozzles 249c and 249a, respectively, mixed in the processing chamber 201, and exhausted through the exhaust port 231a. In this case, the oxidizing gas and the catalyst are supplied to the wafers 200. At that time, the valves 243e to 243g may be opened to supply the inert gas into the processing chamber 201 via the nozzles 249a to 249c, respectively.

By supplying an oxidizing gas and a catalyst to the wafer 200 under processing conditions described later, as illustrated in FIG. 7D, at least a part of the first layer formed on the surface of the base 200b in Step 1 can be oxidized. As a result, a Si-containing layer containing O and C and having a thickness of, for example, less than one atomic layer (one molecular layer) to about several atomic layers (several molecular layers) is formed as the second layer on the surface of the base 200b. When the second layer is formed, at least a part of the Si-C bond contained in the first layer is held without being cut, and is taken into (left in) the second layer as it is. As a result, the second layer becomes a layer containing a Si-C bond. In the present specification, the Si-containing layer containing O and C is also simply referred to as a SiOC layer. In forming the second layer, impurities, such as Cl, in the first layer constitute a gaseous substance containing at least Cl during the oxidizing reaction by H₂O gas and then the gaseous substance is discharged from the processing chamber 201. The second layer contains less impurities such as Cl than the first layer.

In this step, by supplying the catalyst together with the oxidizing gas, the above-described reaction can be allowed to proceed under a non-plasma atmosphere or under a low temperature condition as described later. As described above, by forming the second layer under a non-plasma atmosphere or under a low temperature condition as described later, the methyl group terminating the surface of the base 200a can be maintained without being eliminated (desorbed) from the surface of the base 200a.

After the first layer formed on the surface of the base 200b is oxidized and changed (converted) to the second layer, the valves 243c and 243d are closed, and the supply of the oxidizing gas and the catalyst into the processing chamber 201 is stopped. Then, based on a processing procedure and processing conditions similar to those for the purge in the surface modification, for example, the gas remaining in the processing chamber 201 is eliminated from the processing chamber 201 (purge).

As processing conditions in this step,
oxidizing gas supply flow rate: 1 to 2,000 sccm,
catalyst supply flow rate: 1 to 2,000 sccm,
inert gas supply flow rate (per gas supply pipe): 0 to 20,000 sccm,
supply time of each gas: 1 to 60 seconds,
processing temperature: room temperature to 120° C., preferably room temperature to 100° C., and
processing pressure: 133 to 1,333 Pa
are exemplified.

As the oxidizing gas, for example, an O-containing gas containing an O-H bond such as vapor (H₂O gas) or hydrogen peroxide (H₂O₂) gas can be used. As the oxidizing gas, hydrogen (H₂) gas+oxygen (O₂) gas, H₂ gas+ozone (O₃) gas, and the like can be used. One or more of these gases can be used as the oxidizing gas.

### Predetermined Number of Times of Execution

By performing a cycle of non-simultaneously, that is, non-synchronously, performing Steps 1 and 2 described above a predetermined number of times (n times, n is an integer of 1 or more; and), as illustrated in FIG. 7E, a SiOC film can be selectively formed on the surface of the base 200b among the bases 200a and 200b exposed on the surface of the wafer 200. The above-described cycle is preferably repeated a plurality of times. That is, preferably, the cycle described above is repeated a plurality of times until a formed film has a desired thickness due to a stack of second layers, in which the thickness of the second layer formed per single cycle is smaller than the desired thickness.

After the selective growth is completed, the output of the heater 207 is adjusted so that the temperature in the processing chamber 201, that is, the temperature of the wafer 200 after the SiOC film is selectively formed on the surface of the base 200b is equal to or higher than the temperature of the wafer 200 in the selective growth, preferably higher than the temperature of the wafer 200 in the selective growth, and the post-processing is performed on the wafer 200 after the selective growth. As a result, as shown in FIG. 7F, a methyl group that terminates the surface of the base 200a can be desorbed and removed from the surface of the base 200a, or the function of the methyl group as an inhibitor can be invalidated. As a result, it is possible to reset the surface state of the base 200a and to advance a film forming process and the like on the surface of the base 200a in a subsequent process. Note that this step may be performed in a state where a gas (assist gas) that promotes removal (desorption) of methyl groups such as an inert gas, H₂ gas, or O₂ gas is supplied into the processing chamber 201, or may be performed in a state where supply of the assist gas into the processing chamber 201 is stopped.

As processing conditions in this step,
assist material gas supply flow rate: 0 to 50,000 sccm,
processing gas supply time: 1 to 18,000 seconds,
processing temperature: 120 to 1,000° C., preferably, 120 to 200° C., and
processing pressure: 1 to 120,000 Pa
are exemplified.

### (After-Purge and Atmospheric Pressure Restoration)

After the selective formation of the SiOC film on the surface of the base 200b is completed and the reset of the surface state of the base 200a is completed, an inert gas as a purge gas is supplied from each of the nozzles 249a to 249c into the processing chamber 201 and exhausted from the exhaust port 231a. As a result, the inside of the processing chamber 201 is purged, and a gas and a reaction by-product remaining in the processing chamber 201 are removed from the inside of the processing chamber 201 (after-purge). Thereafter, the atmosphere in the processing chamber 201 is replaced with the inert gas (inert gas replacement), so that the pressure in the processing chamber 201 is restored to a normal pressure (atmospheric pressure restoration).

### (Boat Unload and Wafer Discharge)

After that, the boat elevator 115 lowers the seal cap 219, and the lower end of the manifold 209 is opened. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed by the shutter 219s via the O-ring 220c (shutter close). After being unloaded to the outside of the reaction tube 203, the processed wafer 200 is taken out from the boat 217 (wafer discharge).

### (3) Effects of Present Embodiment

According to the present embodiment, effects below can be obtained.

In the present embodiment, a wall surface facing the processing space 212 in the processing vessel 210 and a surface of the constituent member 214 facing the processing space 212 are each covered with a fluorine-containing substance. The fluorine-containing substance is selected according to a processing temperature of the wafer 200. Specifically, the inner wall surface of the reaction tube 203 is covered with the fluorine-containing substance F1, the inner wall surface of the manifold 209 is covered with the fluorine-containing substance F2, and the surface of the seal cap 219 is covered with the fluorine-containing substance F4. In addition, the surface of the boat 217 is covered with the fluorine-containing substance F5, and the surfaces of the nozzle 249a, the nozzle 249b, and the nozzle 249c are covered with the fluorine-containing substances F6, F7, and F8. That is, since the surfaces of the elements (inner wall surface of the processing vessel 210, the boat 217, the seal cap 219, the nozzle 249a, the nozzle 249b, the nozzle 249c, and the like) other than the substrate disposed in the processing space 212 are C-F terminated, adsorption of atoms and molecules such as the source gas, the modifying gas, the oxidizing gas, and the etching gas used in the above-described substrate processing step can be suppressed. That is, it is possible to suppress the residue of the gas used for processing the wafers 200 in the processing space 212. As a result, film adhesion to quartz members such as the reaction tube 203 is reduced, and extension of the replacement cycle and extension of the cleaning cycle of the reaction tube 203 can be expected. Similarly, the film adhesion to the constituent member 214 is reduced, and extension of the replacement cycle and extension of the cleaning cycle of the constituent member 214 can be expected.

In addition, in the present embodiment, since adsorption of atoms and molecules such as the source gas, the modifying gas, the oxidizing gas, and the etching gas to the wall surface of the processing vessel 210 and the surface of the constituent member 214 is suppressed, the occurrence of the film thickness drop of the processed wafer 200 is suppressed. Furthermore, a variation in deposition due to an influence of moisture generated by film adhesion to the wall surface of the processing vessel 210 (cleaning of the inside of the processing vessel 210 is required) and a variation in the etching rate in the first preprocessing step are suppressed.

In the present embodiment, it is configured to be covered with different fluorine-containing substances according to the positions of the inner wall surface of the processing vessel 210, the surface of the constituent member 214, and the wafer 200 disposed in the processing space 212. According to this configuration, regardless of the arrangement of the wafers 200, it is possible to suppress the adsorption of atoms and molecules such as the source gas and the etching gas to the wall surface of the processing vessel 210 other than the wafers 200 arranged in the processing space 212 and the surface of the constituent member 214. As a result, film adhesion to quartz members such as the reaction tube 203 is reduced, and extension of the replacement cycle and extension of the cleaning cycle of the reaction tube can be expected.

In the present embodiment, the fluorine-containing substance F1 covering the inner wall surface of the reaction tube 203 has a higher infrared transmittance than the fluorine-containing substance covering the surface of the constituent member 214 and the surface of the flange 203c. Therefore, it is possible to heat the wafer 200 by causing radiant heat from the heater 207 provided outside the processing vessel 210 to reach the wafer 200 without being affected by the fluorine-containing substance F1.

In the present embodiment, a portion of the boat 217 not facing the processing space 212 is configured not to be covered with the fluorine-containing substance F5. As an example, the bottom plate 12 which is the lower end portion of the boat 217 is configured not to be covered with the fluorine-containing substance F4. In addition, the fluorine-containing substance covering the surface (upper surface) of the supporting pin 16, which is the portion in contact with the wafer 200, has the largest friction coefficient among the fluorine-containing substances. On the other hand, the back surface (lower surface) of the supporting pin 16 which is a portion of the supporting pin 16 which is not in contact with the wafer 200 is not covered with the fluorine-containing substance. With such a configuration, since the wafer 200 can be placed on the supporting pin 16 without being affected by the coating substance (fluorine-containing substance), the transfer of the wafer 200 can be executed with high accuracy.

In the present embodiment, the processing temperature in the substrate processing step is configured to be lower than the heat-resistant temperature of the fluorine-containing substance. Therefore, the wafer 200 can be processed without being affected by the coating substance (fluorine-containing substance). Although the formation of the SiOC film has been described above, the SiOC film can be applied to, for example, any other film formation as long as the SiOC film can be formed at a temperature lower than the heat-resistant temperature of the fluorine-containing substance.

In the present embodiment, the constituent member 214 is made of a material having high thermal conductivity. With such a configuration, heat can be efficiently applied to the wafers 200 supported by the boat 217, and the wafers 200 can be processed without being affected by the covering material (fluorine-containing substance).

In the present embodiment, at least one metal of Fe, Al, Au, Ag, Cu, Ni, Cr, Co, Zr, Hf, or an alloy thereof may be selected as the material of the boat 217 as the constituent member 214. With such a material, it is possible to obtain high thermal conductivity while securing rigidity of the boat 217. All the members constituting the boat 217 may be made of the same material or different materials. However, in this case, since metal contamination is concerned, it is preferable to cover not only the portion facing the processing space 212 but also the entire boat 217 with the fluorine-containing substance.

Further, the nozzle 249a, the nozzle 249b, and the nozzle 249c may be made of a material having a high thermal conductivity similarly to the boat 217. Specifically, as the materials of the nozzle 249a, the nozzle 249b, and the nozzle 249c, at least one metal of stainless steel, Fe, Al, Au, Ag, Cu, Ni, Cr, Co, Zr, Hf, or an alloy thereof may be selected and used. The materials of the nozzle 249a, the nozzle 249b, and the nozzle 249c may be the same or different. However, in this case, since metal contamination is concerned, it is preferable to cover not only the portion facing the processing space 212 but also the entire nozzle 249 with the fluorine-containing substance.

In the present embodiment, as the fluorine-containing substance, any one fluorine-based resin of PTFE (polytetrafluoroethylene), PFA (perfluoroalkoxy alkane), ETFE (ethylene-tetrafluoroethylene copolymer), FEP (perfluoroethylene-propene copolymer), PVDF (polyvinylidene fluoride), PCTFE (polychlorotrifluoroethylene), and ECTFE (ethylene-chlorotrifluoroethylene copolymer) is selected. By using such a fluorine-containing substance, the inner wall surface of the reaction tube 203, the inner wall surface of the manifold 209, the surface of the seal cap 219, the surface of the boat 217, the surface of the nozzle 249a, the surface of the nozzle 249b, and the surface of the nozzle 249c can be covered with the fluorine-containing substance. In the present embodiment, particularly, it is possible to terminate with carbon fluoride (C-F), and thus, in the substrate processing step, it is possible to effectively suppress adsorption of atoms and molecules such as a source gas and an etching gas to the wall surface of the processing vessel 210 and the surface of the constituent member 214. However, since the heat-resistant temperature of the fluorine-containing film is currently about 300° C., it is preferable to use the fluorine-containing film so that the temperature in the processing vessel 210 does not exceed this heat-resistant temperature.

### Other Embodiments of Present Disclosure

One embodiment of the present disclosure has been specifically described above. However, the present disclosure is not limited to the embodiment described above, and thus various modifications can be made without departing from the gist of the present disclosure. For example, in the above-described embodiment, the wall surface of the processing vessel 210 and the surface of the constituent member 214 are covered with a fluorine-based resin which is a fluorine-containing substance, but the present disclosure is not limited thereto. Instead of the fluorine-based resin, a fluorine-based passive film may be formed on the wall surface of the processing vessel 210 and the surface of the constituent member 214. Further, a fluorine-based passive film may be formed on the surface of the flange 203c of the reaction tube 203. As the fluorine-based passive film, at least one of a fluorine-passive film of nickel fluoride (NiF) or chromium fluoride (CrF) is selected.

Furthermore, the fluorine-containing substance covering the wall surface of the processing vessel 210 and the surface of the constituent member 214 may be selected from a fluorine-based resin or a fluorine-based passive film according to the position from the wafer 200. For example, the inner wall surface of the processing vessel 210 may be covered with a fluorine-based resin, and a fluorine-based passive film may be formed on the surface of the constituent member 214, or a fluorine-based passive film may be formed on the inner wall surface of the processing vessel 210, and the surface of the constituent member 214 may be covered with a fluorine-based resin.

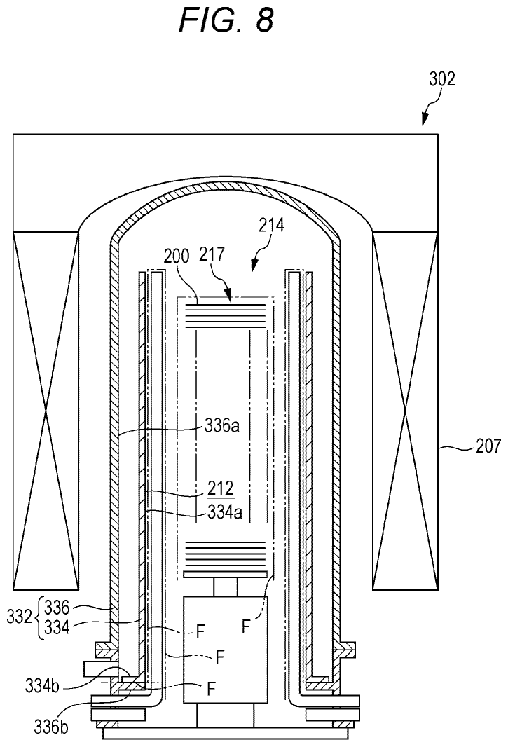

In the above-described embodiment, the reaction tube 203 of the processing furnace 202 is formed of one cylindrical body, but the present disclosure is not limited thereto. For example, as in a processing furnace 302 illustrated in FIG. 8, the reaction tube 332 may include an inner pipe 334 forming a processing space therein, an outer pipe 336 provided outside the inner pipe 334, and flanges 334a and 336a provided below the inner pipe 334 and the outer pipe 336. Here, the inner surface of the reaction tube 332 facing the wafers 200, for example, the inner surface 334a of the inner pipe 334 may be covered with a fluorine-containing substance, or a fluorine-based passive film may be formed on the surface of the flange 334a. As described above, by coating the reaction tube 332 facing the wafer 200 with the fluorine-based resin and forming the passive film on the flange 334a not facing the wafer 200, extension of the maintenance cycle can be expected. Furthermore, the inner surface 334a of the inner pipe 334 may be coated with a fluorine-based resin, and the inner surface 336a of the outer pipe 336 may not be coated with a fluorine-based resin. As described above, the inner pipe 334 facing the wafer 200 is coated with the fluorine-based resin, and the outer pipe 336 not facing the wafer 200 is not coated with the fluorine-based resin, so that extension of the maintenance cycle can be expected.

In addition, for example, in each of the above-described embodiments, the film forming processing in the semiconductor device has been described as an example of the processing performed by the substrate processing apparatus, but the present disclosure is not limited thereto. That is, other than the film forming processing, processing of forming an oxide film and a nitride film or processing of forming a film containing metal may be adopted. The specific content of the substrate processing may be any content, and the present disclosure can be suitably applied not only to the film forming processing but also to other substrate processing such as annealing processing, oxidizing processing, nitriding processing, diffusing processing, and lithography processing.

Furthermore, the present disclosure can also be suitably applied to, for example, another substrate processing apparatus such as an annealing processing apparatus, an oxidizing processing apparatus, a nitriding processing apparatus, an exposure apparatus, a coating apparatus, a drying apparatus, a heating apparatus, or a processing apparatus using plasma. In addition, in the present disclosure, these apparatuses may be mixed.

Furthermore, the present disclosure can be applied not only to a semiconductor manufacturing apparatus but also to an apparatus that processes a glass substrate, such as an LCD apparatus.

All documents, patent applications, and technical standards described in the present specification are incorporated herein by reference to the same extent as a case where each of the individual documents, the patent applications, and the technical standards is specifically and individually described to be incorporated by reference.

According to the present disclosure, it is possible to suppress the residue of gas used for substrate processing.

What is claimed is:

1. A substrate processing apparatus comprising:
a processing vessel provided with a processing space in which a substrate is processed; and
a constituent member disposed in the processing space,
wherein
a wall surface facing the processing space provided in the processing vessel and a surface of the constituent member facing the processing space are each covered with a fluorine-containing substance, and
the fluorine-containing substance is selected according to a processing temperature of the substrate.

2. The substrate processing apparatus according to claim 1, wherein the wall surface and the surface are covered with different fluorine-containing substances according to positions of the surface of the constituent member facing the wall surface of the processing vessel and the processing space, and the substrate disposed in the processing space.

3. The substrate processing apparatus according to claim 2, wherein
the processing vessel includes a reaction tube and a flange provided below the reaction tube, and
the fluorine-containing substance covering the surface of the reaction tube is higher in infrared transmittance than the fluorine-containing substance covering the surface of the constituent member and the surface of the flange.

4. The substrate processing apparatus according to claim 1, wherein
the constituent member includes a support tool capable of supporting the substrate, and
a portion of the support tool not facing the processing space is not covered with the fluorine-containing substance.

5. The substrate processing apparatus according to claim 4, wherein a lower end portion of the support tool is not covered with the fluorine-containing substance.

6. The substrate processing apparatus according to claim 4, wherein
the support tool includes a placement portion on which the substrate is placed, and
the fluorine-containing substance covering the surface of the placement portion has the largest friction coefficient among the fluorine-containing substances.

7. The substrate processing apparatus according to claim 4, wherein
the support tool includes a placement portion on which the substrate is placed, and
a surface of the placement portion that is in contact with the substrate is not covered with the fluorine-containing substance.

8. The substrate processing apparatus according to claim 1, wherein a heat-resistant temperature of the fluorine-containing substance is higher than the processing temperature.

9. The substrate processing apparatus according to claim 1, wherein the constituent member is made of a material having a high thermal conductivity.

10. The substrate processing apparatus according to claim 1, wherein at least one metal selected from the group of Fe, Al, Au, Ag, Cu, Ni, Cr, Co, Zr, or Hf, and an alloy thereof is selected as a material of the constituent member.

11. The substrate processing apparatus according to claim 1, wherein any one fluorine-based resin selected from the group of PTFE, PFA, ETFE, FEP, PVDF, PCTFE, or ECTFE is selected as the fluorine-containing substance.

12. The substrate processing apparatus according to claim 2, wherein the wall surface of the processing vessel and the surface of the constituent member facing the processing space are C-F terminated.

13. The substrate processing apparatus according to claim 2, wherein the fluorine-containing substance is formed by coating with a fluorine-based resin or forming a fluorine-based passive film.

14. The substrate processing apparatus according to claim 13, wherein
the processing vessel includes a reaction tube and a flange provided below the reaction tube, and
the passive film can be formed on a surface of the flange.

15. The substrate processing apparatus according to claim 13, wherein
the processing vessel includes an inner pipe that forms the processing space inside, an outer pipe that is provided outside the inner pipe, and a flange that is provided below the inner pipe and the outer pipe, and
the passive film can be formed on a surface of the flange.

16. The substrate processing apparatus according to claim 15, wherein
the inner pipe is coated with a fluorine-based resin, and
the outer pipe is not coated with the fluorine-based resin.

17. A processing vessel provided with a processing space in which a substrate is processed, wherein
a wall surface facing the processing space provided in the processing vessel and a surface of a constituent member disposed in the processing space are each covered with a fluorine-containing substance, and
the fluorine-containing substance is selected according to a processing temperature of the substrate.

18. A method of manufacturing a semiconductor device, comprising:
loading a substrate in a processing vessel; and processing the substrate loaded in the processing vessel,
wherein a wall surface facing a processing space in which the substrate is processed and that is provided in the processing vessel, and a surface of a constituent member disposed in the processing space are each covered with a fluorine-containing substance, and
wherein the fluorine-containing substance is selected according to a processing temperature of the substrate.
